(19) United States
(12) Patent Application Publication
(10) Pub. No.: US 2024/0095427 A1
(43) Pub. Date: Mar. 21, 2024

(54) APPARATUS AND METHOD OF SYNTHETIC DATA GENERATION USING ENVIRONMENTAL MODELS

(71) Applicant: Korea University of Technology and Education Industry-University Cooperation Foundation

(72) Inventors: Won-Tae Kim, Cheonan-si (KR); Hanjin Kim, Cheongju-si (KR); Youngjin Kim, Cheongju-si (KR)

(73) Assignee: Korea University of Technology and Education Industry-University Cooperation Foundation, Cheonan-si (KR)

(21) Appl. No.: 18/083,612

(22) Filed: Dec. 19, 2022

(30) Foreign Application Priority Data
Sep. 20, 2022 (KR) 10-2022-0118325

(51) Int. Cl. G06F 30/27

(52) U.S. Cl. CPC G06F 30/27

(57) ABSTRACT

Disclosed are a method and an apparatus of synthetic data generation for training an artificial intelligence model. The method includes: reading a target environmental model simulating a target environment to generate synthetic data among a plurality of environmental models simulating a plurality of actual environments, respectively; extracting an environmental feature which influences generation of data in the target environment; configuring a synthetic data generation function of a synthetic data generation simulator for the target environmental model so that the synthetic data reflects the environmental feature; and generating the synthetic data by using the synthetic data generation simulator for the target environmental model, and has an effect of being capable of generating high-quality learning synthetic data which may be used for training an artificial intelligence model.

### CROSS-REFERENCE TO RELATED APPLICATIONS

This application claims the benefit of Korean patent application no. 10-2022-0118325 filed on Sep. 20, 2022, which is incorporated herein by reference for all purposes as if fully set forth herein.

### TECHNICAL FIELD

The present disclosure relates to generation of data for training an artificial intelligent model, and more particularly, to an apparatus and a method of generating high-quality learning synthetic data using environmental models.

### BACKGROUND

As the field of artificial intelligence is diversified today, and its importance increases, data securing naturally is essentially discussed. The important of data of an artificial intelligence age is very large enough to be compared with crude oil of the tertiary industry resolution, and the quality of the data exerts a direct influence on the performance of the artificial intelligence, so importance of data securing becomes gradually higher. However, it is not easy to collect data for the artificial intelligence due to cost, time or security, and it is very difficult to immediately measure or collect data required for developing the artificial intelligence in some industrial fields such as disasters.

In recent years, to solve such a problem, synthetic data generation techniques that generate virtual data that simulate actual data through computer simulation or algorithms have been attracting attention. The synthetic data can be generated through the combination of two methods through a virtual environment (e.g., a simulation environment) and synthetic algorithms other than data that are not collected or measured in the actual environment. The synthetic data generation techniques have the advantage of securing data diversity in terms of cost and time reduction, personal information protection, as well as utilization of virtual environments that are not physically controlled.

The above disclosed contents are to just help understand the background art of the technical ideas of the present disclosure, therefore cannot be understood as a prior art known to those skilled in the art of the technical field of the present disclosure.

### SUMMARY

How generated synthetic data can well reflect actual data, i.e., whether the generated synthetic data has high effectiveness is most important when synthetic data is generated. Effectiveness being important means that the synthetic data well reflects features of the actual data, which becomes a measure of synthetic data quality.

The existing synthetic data generation method has an advantage in that various data can be secured because data can be generated without a temporal or physical constraint, but has a problem in that synthetic data slightly different from the features of the actual data can be generated because a virtual environment or a statistical model is used.

An exemplary embodiment of the present disclosure has been made in an effort to allow generated synthetic data to normally reflect features of actual data by using an environmental model simulating an actual environment.

The objects to be solved by the present disclosure are not limited to the aforementioned objects, and other objects, which are not mentioned above, will be apparent to a person having ordinary skill in the art from the following description.

The present disclosure presents a method of synthetic data generation for training an artificial intelligence model. The method may include: reading a target environmental model simulating a target environment to generate synthetic data among a plurality of environmental models simulating a plurality of actual environments, respectively; extracting an environmental feature which influences generation of data in the target environment; configuring a synthetic data generation function of a synthetic data generation simulator for the target environmental model so that the synthetic data reflects the environmental feature; and generating the synthetic data by using the synthetic data generation simulator for the target environmental model, and has an effect of being capable of generating high-quality learning synthetic data which may be used for training an artificial intelligence model.

The method of synthetic data generation for training an artificial intelligence model and other exemplary embodiments may include the following features.

According to the exemplary embodiment, the extracting of the environmental feature which influences generation of data in the target environment may be extracting the environmental feature based on a correlation between the target environment and an application field of the synthetic data.

According to the exemplary embodiment, the correlation between the target environment and the application field of the synthetic data may be determined based on ontology related to the target environment and the application field of the synthetic data.

According to the exemplary embodiment, further, the configuring of the synthetic data generation function of the synthetic data generation simulator for the target environmental model so that the synthetic data reflects the environmental feature may be modifying a parameter corresponding to each environmental feature among parameters of the synthetic data generation function according to the environmental feature.

According to the exemplary embodiment, further, the method may further include matching the data feature of the synthetic data generated by the synthetic data generation simulation for the target environmental model with a data feature to which the actual data generated in the target environment belongs.

According to the exemplary embodiment, further, the matching of the data feature of the synthetic data generated by the synthetic data generation simulation for the target environmental model with the data feature to which the actual data generated in the target environment belongs may include receiving the actual data acquired in the target environment, determining a data distribution region of the synthetic data generated by the synthetic data generation simulator for the actual data as a data distribution region to which the actual data belongs, and setting the synthetic data generation simulator to output only synthetic data included in the data distribution region to which the actual data belongs among the synthetic data generated by the synthetic data generation simulator.

Meanwhile, the present disclosure presents an apparatus of synthetic data generation for training an artificial intelligence model. The apparatus may include: an environmental model database storing environmental models simulating a plurality of actual environments, respectively; an environmental feature analysis unit reading, from the environmental model database, a target environmental model simulating a target environment to generate synthetic data among the plurality of environmental models, and extracting an environmental feature which influences generation of data in the target environment; and a synthetic data generation unit configuring a synthetic data generation function of a synthetic data generation simulator for the target environmental model so that the synthetic data reflects the environmental feature, and generating the synthetic data by suing the synthetic data generation simulator for the target environmental model.

The apparatus of synthetic data generation and other exemplary embodiments may include the following features.

According to the exemplary embodiment, the environmental feature analysis unit may extract the environmental feature based on a correlation between the target environment and an application field of the synthetic data.

According to the exemplary embodiment, further, the environmental feature analysis unit may determine the correlation based on ontology related to the target environment and the application field of the synthetic data.

According to the exemplary embodiment, further, the synthetic data generation unit may modify a parameter corresponding to each environmental feature among parameters of the synthetic data generation function according to the environmental feature.

According to the exemplary embodiment, further, the apparatus may further include a data collection unit collecting actual data acquired in the target environment, and the synthetic data generation units may further match the data feature of the synthetic data generated by the synthetic data generation simulation for the target environmental model with a data feature to which the actual data belongs.

According to the exemplary embodiment, further, the synthetic data generation unit may determine a data distribution region of the synthetic data generated by the synthetic data generation simulator for the actual data as a data distribution region to which the actual data belongs, and set the synthetic data generation simulator to output only synthetic data included in the data distribution region to which the actual data belongs among the synthetic data generated by the synthetic data generation simulator.

On another hand, the present disclosure presents an electronic device for synthetic data generation for training an artificial intelligence model. The electronic device may include: a communication circuit; a memory; and a processor operatively connected to the memory, and when the memory is executed, the processor may read a target environmental model simulating a target environment to generate synthetic data among a plurality of environmental models simulating a plurality of actual environments, respectively, extract an environmental feature which influences generation of data in the target environment, configure a synthetic data generation function of a synthetic data generation simulator for the target environmental model so that the synthetic data reflects the environmental feature, and store instructions to generate the synthetic data by using the synthetic data generation simulator for the target environmental model.

The electronic device and other exemplary embodiments may include the following features.

According to the exemplary embodiment, the instructions may allow the processor to extract an environmental feature which influences generation of data in the target environment, and extract the environmental feature based on a correlation between the target environment and an application field of the synthetic data.

According to the exemplary embodiment, further, the instructions may allow the processor to determine the correlation based on ontology related to the target environment and the application field of the synthetic data.

According to the exemplary embodiment, further, the instructions allow the processor to modify a parameter corresponding to each environmental feature among parameters of the synthetic data generation function according to the environmental feature.

According to the exemplary embodiment, further, the instructions allow the processor to match the data feature of the synthetic data generated by the synthetic data generation simulation for the target environmental model with a data feature to which the actual data generated in the target environment belongs.

According to the exemplary embodiment, further, the instructions allow the processor to receive actual data acquired in the target environment, determine a data distribution region of the synthetic data generated by the synthetic data generation simulator for the actual data as a data distribution region to which the actual data belongs, and set the synthetic data generation simulator to output only synthetic data included in the data distribution region to which the actual data belongs among the synthetic data generated by the synthetic data generation simulator.

According to an exemplary embodiment disclosed in the present disclosure, there is an effect that a synthetic data set showing features of actual data is generated to solve a problem in cost, time, and security, which obtain actual data for artificial intelligence learning.

Further, according to an exemplary embodiment of the present disclosure, there is an effect that high-quality synthetic data can be generated by normally reflecting features of learning data for an actual environment based on an environmental model for the actual environment.

Further, according to an exemplary embodiment of the present disclosure, there is an effect that the performance of an artificial intelligence model deteriorates as a distribution of data used upon artificial intelligence learning shows a difference from a data distribution of the actual environment to which artificial intelligence is to be applied.

Further, according to an exemplary embodiment of the present disclosure, there is an effect that generalization performance can be enhanced by relieving an overfitting problem of the artificial intelligence model based on high-quality large-capacity synthetic data secured based on the environmental model.

Meanwhile, effects which can be obtained in the present disclosure are not limited to the aforementioned effects and other unmentioned effects will be clearly understood by those skilled in the art from the following description.

### BRIEF DESCRIPTION OF THE DRAWINGS

The accompanying drawings of this specification exemplify a preferred exemplary embodiment of the present disclosure, the spirit of the present disclosure will be more clearly understood from the following detailed description taken in conjunction with the accompanying drawings, and thus it will be understood that the present disclosure is not limited to only contents illustrated in the accompanying drawings.

FIG. 1 is a conceptual view for describing a method of synthetic data generation using environmental models.

FIG. 2 is a block diagram illustrating a configuration of an apparatus of synthetic data generation according to an exemplary embodiment.

FIG. 3 is a block diagram illustrating a configuration of an apparatus of synthetic data generation according to an exemplary embodiment.

FIG. 4 is a diagram illustrating an example of ontology representing a correlation between an actual environment and an application field of synthetic data.

FIG. 5 is a diagram illustrating an example of ontology representing a correlation between the actual environment and a communication field.

FIG. 6 is a diagram illustrating an example of ontology representing a correlation between the actual environment and an air-conditioning field.

FIG. 7 is a diagram illustrating an example of ontology representing a correlation between the actual environment and a fire field.

FIG. 8 is a diagram illustrating an example of adding the correlation in the ontology representing the correlation between the actual environment and the fire field.

FIG. 9 is a flowchart for describing a method of synthetic data generation according to exemplary embodiments.

### DETAILED DESCRIPTION

A technology disclosed in the present disclosure may be applied to an apparatus and a method of synthetic data generation for training an artificial intelligence model. However, the technology disclosed in the present disclosure is not limited thereto, but may also be applied to all apparatuses and methods to which a technical spirit of the technology may be applied.

It should be noted that the technical terms used herein are only used to describe a specific embodiment, and are not intended to limit the spirit of the present disclosure. Further, the technical term used herein should be interpreted as meaning generally understood by a person with ordinary knowledge in the field to which the present disclosure belongs, unless otherwise defined herein. The technical term used herein should not be interpreted as excessively comprehensive or excessively reduced meaning. Further, when the technical term used herein is an incorrect technical term that does not accurately express the idea of the present disclosure, a person with ordinary knowledge in the field to which the present disclosure belongs may correctly understand the same and replace the same with a correct term. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Hereinafter, embodiments disclosed herein will be described in detail with reference to the accompanying drawings. Identical or similar constituent elements are denoted by the same reference numerals, and redundant descriptions thereof will be omitted.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

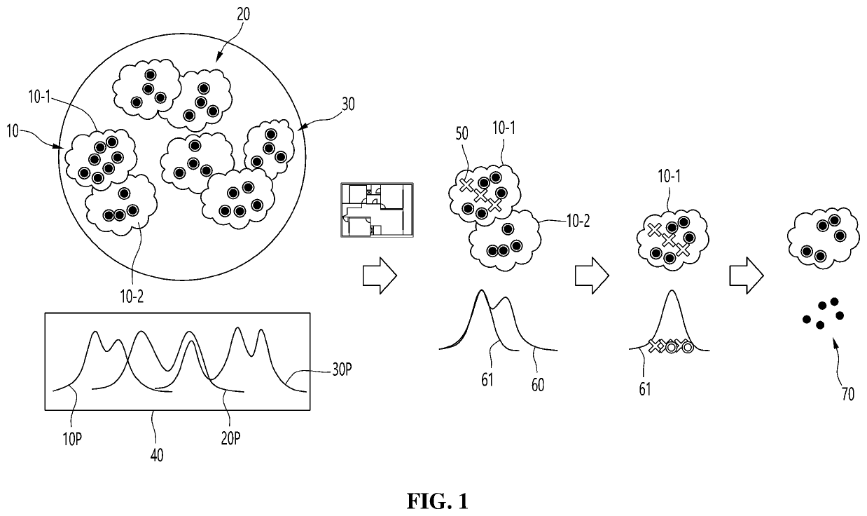

FIG. 1 is a conceptual view for describing a method of synthetic data generation using environmental models.

In general, data generated in a specific environment may have different data distributions according to features of an actual environment. The present disclosure analyzes and derives features for the actual environment, i.e., features of an environment which may influence generation of data in the actual environment by using an environmental model simulating the actual environment, and matches a distribution of synthetic data to be generated based on environmental features to be closer to a distribution of data to which actual data is to belong to generate high-quality synthetic data. Here, an environmental model may be digital twin, a building model, or a building information modeling (BIM) model for a targeted actual environment.

Referring to FIG. 1, when it is assumed that there are three actual environments of environment A, environment B, and environment C, data (e.g., communication data between a transmitter and a receiver, flame spread data, etc.) generated in a building corresponding to each environment may have different data distributions such as a data distribution 10 generated in environment A, a data distribution 20 generated in environment B, and a data distribution 30 generated in environment C according to different environmental features. Reference numeral 40 represents a probability distribution of data generable in environment A, environment B, and environment C, and reference numeral 10P represents a data probability distribution of environment A, reference numeral 20P represents a data probability distribution of environment B, and reference numeral 30P represents a data probability distribution of environment C.

Data are positioned and distributed close to each other as a similarity is higher (e.g., has features that sample data are positioned close to each other in a latent space), and since various environmental features such as placement of objects constituting a space, a material of a wall, whether there is an element influencing a property of data in a surrounding, etc., are reflected to a generation result of data in addition to features that environment A, environment B, and environment C are different spaces, the distribution of the data may be divided more specifically even in the same distribution group of the data environment 10 of environment A, the data distribution 20 of environment B, and the data distribution 30 of environment C. The specific data distribution is displayed like forms of respective clouds 10-1 and 10-2 crumpled into one lump even in the same distribution group of the data distribution 10 of environment A, for example. The cloud form data distribution 10-1 and the cloud form data distribution 10-2 may be called the latent space.

Here, additionally, when the characteristics of the actual environment is utilized, the characteristics of the actual environment may be reflected to the environmental model by comparing with a method of randomly generating data by a conventional simple simulation, so a data feature of the actual data may be easily known, and higher-quality synthetic data may be generated through the data feature. It may be regarded that data having a similarity belong to the same data distribution, and it may be regarded that the data belonging to the same data distribution have a similar feature. In the present disclosure, a factor which influences a similar feature of actual data may be referred to as a feature (environmental feature) of an actual environment, and the feature of the actual environment is extracted based on the environmental model, which may be utilized for finding (approximating or estimating) a distribution of data more similar to the actual data. When the synthetic data is generated by utilizing the derived data distribution, high-quality synthetic data to which the feature of the actual environment is well reflected may be generated.

That is, the feature of the data may depend on a location of a data generation apparatus in the space, placement of an object constituting the space at a specific time, etc., in spite of a structurally same environment, and data collected in environments having a similar feature have a similar distribution. Since there are numerous features which influence the feature of the data in addition to the actual environmental feature, it is difficult that the feature of the synthetic data well reflects the feature of the actual data even though the synthetic data is generated by utilizing an actual data sample in the existing synthetic data generation techniques that randomly generate data.

For example, in the synthetic data generation method disclosed in the present disclosure, when data generation for actual environment A is targeted, environmental model A corresponding to actual environment A among various environmental models is selected, and then an environmental feature related to actual environment A is extracted from environmental model A, and data is generated by applying the extracted environmental feature to a synthetic data generation simulator for environmental model A. In this case, in the method, a synthetic data generation function or synthetic data generation logic of the synthetic data generation simulator is configured by using the extracted environmental feature, and then targeted data is generated in the synthetic data generation simulator. Through such a process, in the synthetic data generation method, the data distribution 10 of environment A among the data distribution 10 of environment A, the data distribution 20 of environment B, and the data distribution 30 of environment C may be obtained. Here, additionally, in the method, sampled actual data 50 is acquired in actual environment A or a test bed for actual environment A, and then data generated in the data distribution 10 of environment A matches the probability distribution 10-1 in which actual data is generated based on the acquired actual data 50. The data probability distribution of environment A is represented as a character “m” shape 60, and the data probability distribution 10-1 of environment A in which the actual data is present is represented as a normal probability distribution curve 61. Thus, in the synthetic data generation method according to the present disclosure, the generated data is output into a latent space 10-1 for environment A in which the actual data is present to obtain the high-quality synthetic data 70.

Here, the synthetic data means data having a similar feature to data which may be measured in the actual environment through a statistical/Bayesian method that just generates data with several actual data samples, an algorithm such as an ML mode, etc.

FIG. 1 is a block diagram illustrating a configuration of an apparatus of synthetic data generation according to an exemplary embodiment.

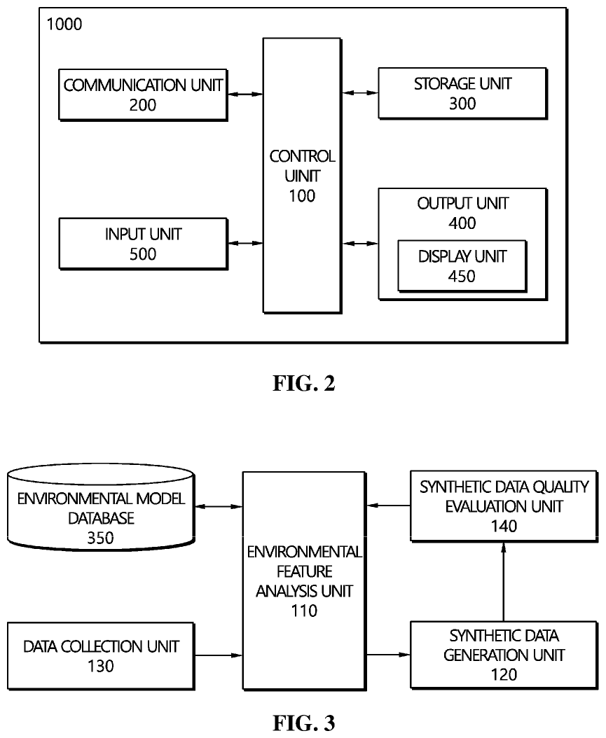

Referring to FIG. 2, a synthetic data generation apparatus 1000 for implementing a method or a function proposed by the present disclosure may include a control unit 100, a storage unit 300, a bus (not illustrated) for data transmission or a communication unit 200 for performing communication with the outside, an output unit 400, and an input unit 500. Illustrated components are not required, so the synthetic data generation apparatus 100 may also be implemented which has more components therethan or less components therethan. Further, the component may be implemented by hardware or software or implemented through a combination of the hardware and the software.

The control unit 100 may mean all types of processing devices which may process data, such as a processor. The control unit 100 may be configured to execute processing logic for performing various operations and steps described in the present disclosure. Here, the ‘processor’ may mean, for example, a data processing device embedded in hardware, which has a physically structurized circuit in order to perform a function expressed by a code or a command included in the program. As such, An example of the data processing device embedded in the hardware may include a processing device such as a Microprocessor, a Central Processing Unit (CPU), a Processor core, a Multiprocessor, an Application-Specific Integrated Circuit (ASIC), A Field Programmable Gate Array (FPGA), etc., but the scope of the present disclosure is not limited thereto.

The communication unit 200 may be constituted by wired and/or wireless communication modules. For example, the communication unit 200 may include wireless communication modules such as Wireless Fidelity (Wi-Fi), Bluetooth, Zigbee, near field communication (NFC), Wireless Broadband Internet (Wibro), etc. The communication unit 200 may transmit/receive data by performing wired/wireless communication with another device through a network.

The network disclosed in the present disclosure may be, for example, a common network such as a wireless network, a wired network, or the Internet, a private network, a global system for mobile communication network (GSM), a general packet radio network (GPRS), a local area network (LAN), a wide area network (WAN), a metropolitan area network (MAN), a cellular network, a public switched telephone network (PSTN), a personal area network, Bluetooth, Wi-Fi Direct, near field communication, an UltraWide band, a combination thereof, or random other networks, but is not limited thereto.

The storage unit 300 may include magnetic storage media or a flash storage media, but the scope of the present disclosure is not limited thereto.

The output unit 400 which is used for generating an output related with sight, hearing, or touch may include, for example, a display unit 450. The display unit 450 may have a mutual layer structure with a touch sensor or may be integrally formed to implement a touch screen. Such a touch screen may serve as a user input unit for providing an input interface between the device and the user and provide an output interface between the device and the user.

The input unit 500 may be connected to the control unit 100 through an input/output interface connected to the bus. The input unit 500 may include a keyboard, a pointing device, a microphone, a joystick, a touch pad, a scanner, and the like. The input/output interface may include any one of very various interfaces such as a serial port interface, a PS/2 interface, a parallel port interface, a USB interface, and an IEEE 1394 interface, or also logically represent a combination of other interfaces.

The control unit 100 may perform a function of the synthetic data generation apparatus 100, i.e., processes and procedures of a method for generating high-quality synthetic data for training the artificial intelligence model by utilizing the environmental model.

FIG. 3 is a block diagram illustrating a configuration of an apparatus of synthetic data generation according to an exemplary embodiment.

Referring to FIG. 3, the synthetic data generation apparatus 1000 may include an environmental feature analysis unit 110, a synthetic data generation unit 120, a data collection unit 130, and an synthetic data quality evaluation unit 140, and the components may be implemented by a program and stored in the storage unit 300, and executed by the control unit 100 (processor), or implemented by a combination of the hardware and the software, and operated. The synthetic data generation apparatus 1000 may further include an environmental model database 350, and the environmental model database 350 may be stored in the storage unit 300 or also stored in an external separate storage device. Illustrated components are not required, so the synthetic data generation apparatus 100 may also be implemented which has more components therethan or less components therethan. The component may be implemented by hardware or software or implemented through a combination of the hardware and the software.

When the environmental feature analysis unit 110 selects an environmental model that simulates an actual environment in which a user intends to generate synthetic data, the environmental feature analysis unit 110 reads the selected environmental model from the environmental model database 350, and then analyze the feature of the actual environment and extracts an environmental feature which influences generation of data from the environmental model. The environmental feature analysis unit 110 may extract the environmental feature based on a correlation between the actual environment and the application field of the synthetic data.

The environmental feature of the environmental model may depend on the actual environment in which data is generated and the application field of the generated synthetic data. For example, when synthetic data of a communication field is generated in a building, whether there is a metallic article in the building, a location of an antenna in the space, etc., become important environmental features, but a flow of air in the building is not a relatively important environmental feature. On the contrary, when synthetic data of a fire field is generated in the building, data related to the flow of the air in the building becomes a very important environmental feature compared with the location of the antenna which is the important environmental feature. The environmental feature analysis unit 110 may utilize ontology as the correlation between the actual environment and the application field of the synthetic data in extracting the environmental feature. The environmental feature analysis unit 110 may derive an association between information included in the environmental model and the application field to generate the synthetic data by utilizing the ontology, and easily extract the environmental feature suitable for the application field to generate the synthetic data by using the derived association.

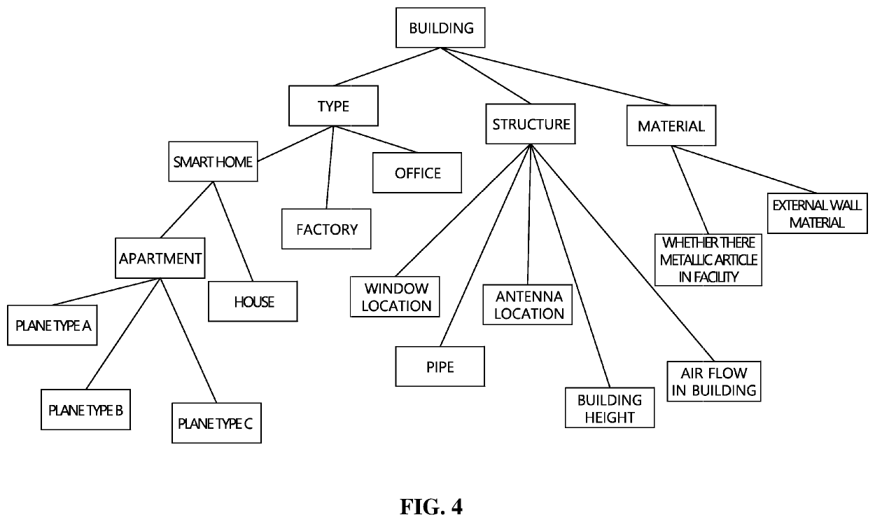

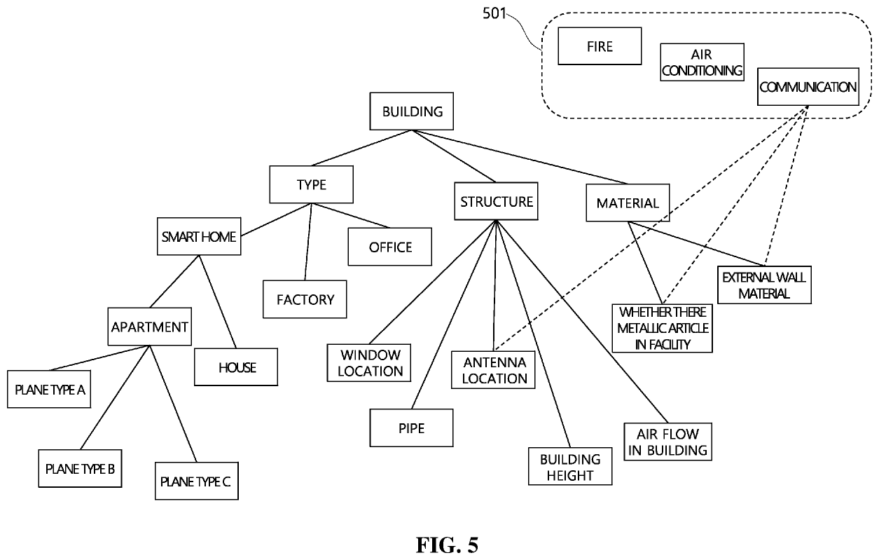

FIG. 4 is a diagram illustrating an example showing a relationship between environmental features which influence generation of data in the actual environment.

Referring to FIG. 4, the environmental feature which influences the generation of the data in the actual environment such as the building may be categorized into the type of building, the structure of the building, and the material of the building, and the type of building may be categorized into a smart home, a factory, an office, etc., again, the structure of the building may be categorized into a window location, a pipe, an antenna location, a building height, whether there is the flow of the air in the building, etc., again, and the material of the building may be categorized into whether there is the metallic article in a facility (building), a material of an external wall, etc., in detail.

Hereinafter, referring to FIGS. 5 to 7, examples of the ontology used for extracting the environmental feature will be described.

FIG. 5 is a diagram illustrating an example of ontology representing a correlation between the actual environment and a communication field.

Referring to FIG. 5, since the environmental feature of the building which influences the data generation in the communication field among application fields 501 of the synthetic data has a correlation with the ‘antenna location’ in the ‘structure’ of the building, ‘whether there is the metallic article in the facility’ in the ‘material’ of the building, and the ‘external wall material’, the environmental feature analysis unit 110 may extract the ‘antenna location’, ‘whether there is the metallic article in the facility’, and the ‘external wall material’ as the environmental feature when generating the synthetic data in the communication field.

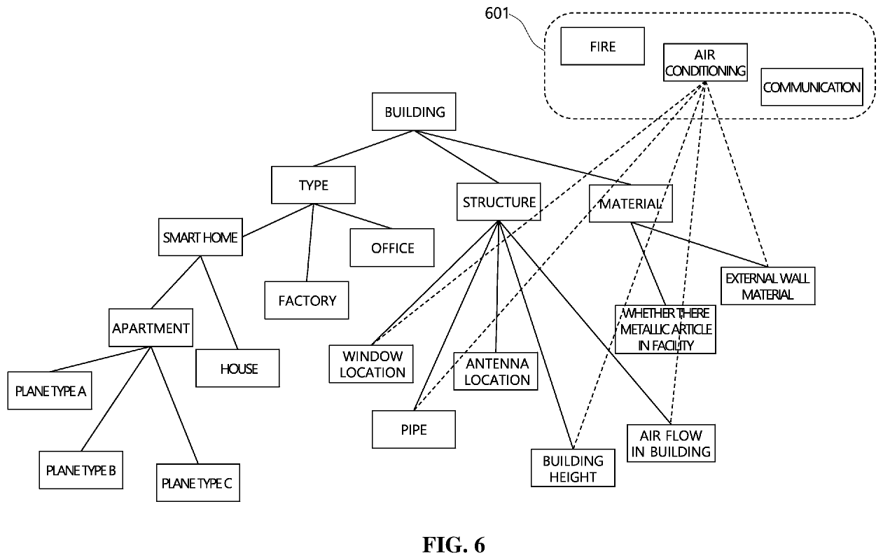

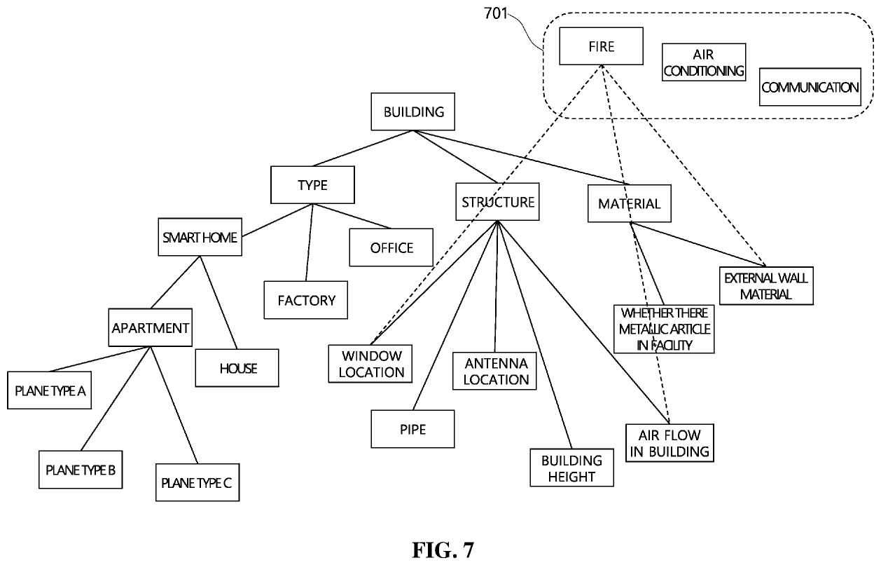

FIG. 6 is a diagram illustrating an example of ontology representing a correlation between the actual environment and an air-conditioning field.

Referring to FIG. 6, since the environmental feature of the building which influences the data generation in the air conditioning field among application fields 601 of the synthetic data has a correlation with the ‘window location’, the ‘pipe’, the ‘building height’, and ‘the flow of the air in the building’, and the ‘external wall material’ in the ‘material’ of the building, the environmental feature analysis unit 110 may extract the ‘window location’, the ‘pipe’, the ‘building height’, and the ‘external wall material’ as the environmental feature when generating the synthetic data in the air conditioning field.

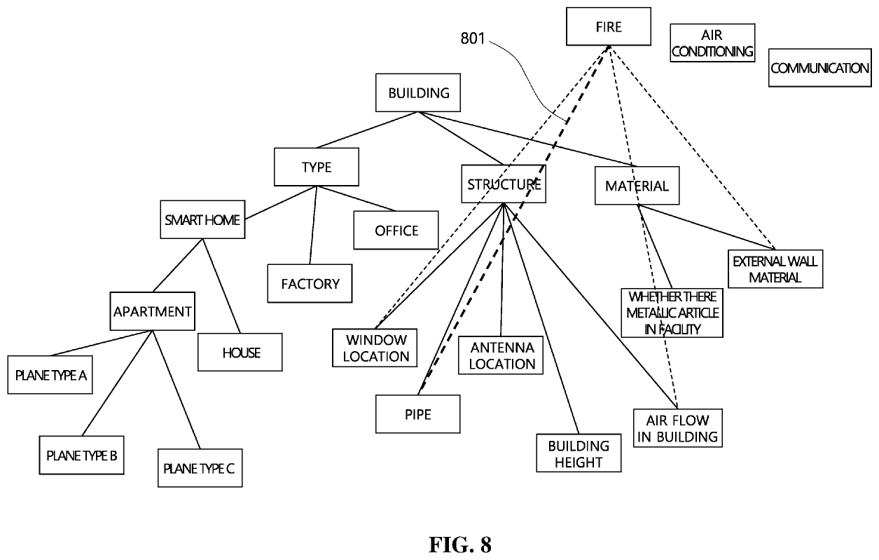

FIG. 7 is a diagram illustrating an example of ontology representing a correlation between the actual environment and a fire field.

Referring to FIG. 7, since the environmental feature of the building which influences the data generation in the fire field among application fields 701 of the synthetic data has a correlation with the ‘window location’, the ‘pipe’, the ‘building height’, and ‘the flow of the air in the building’, and the ‘external wall material’ in the ‘material’ of the building, the environmental feature analysis unit 110 may extract the ‘window location’, the ‘pipe’, the ‘flow of the air in the building’, and the ‘external wall material’ as the environmental feature when generating the synthetic data in the fire field.

In order to derive information associated with the application field of the synthetic data among the features for the actual environment from the environmental model, it should be judged which information is associated with the application field by analyzing the actual environment. The judgment of the association information manually derived by an application field expert may also be used by the environmental feature analysis unit 110 and also performed by the artificial intelligence. The application field expert may directly derive environmental features of the actual environment which have a large correlation with data to be generated based on an experience/knowledge thereof from the environmental model.

The derivation process of the correlation information may be automatically performed through a mathematical model or an artificial intelligence model. For example, when the synthetic data generation apparatus 1000 generates synthetic data in which a specific environmental feature has a better quality than previously while repeating the process of “randomly selecting the environmental feature in the environmental model information, generating environmental data based on the selected feature, and evaluating the quality of the generated synthetic data” by utilizing an ontology graph and an environmental model prepared by basic correlation information, the environmental feature analysis unit 110 may reflect the correlation of the environmental feature to the mathematical model or the artificial intelligence model or learn the correlation. The reflected or learned feature information may be regarded as a strength of a link or a generation of the link in the ontology graph, and an environmental feature having a high correlation to a specific application field may be derived from the environmental model through a change of the strength.

FIG. 8 is a diagram illustrating an example of adding the association relationship in the ontology representing the association relationship between the actual environment and the fire field.

Referring to FIG. 8, a correlation 801 between the application field ‘fire’ and the environmental feature ‘pipe’ is added to the environmental features, the ‘window location’, the ‘flow of the air in the building’, and the ‘external wall material’ when generating the synthetic data in the fire field in FIG. 7, and the environmental feature analysis unit 110 hands over a combination of various environmental features to the synthetic data generation unit 120 to allow the synthetic data generation unit 120 to reflect the combination to the synthetic data generation simulator to generate the synthetic data. When the quality of the synthetic data generated by such a process is more excellent than the quality of the synthetic data according to previous other environmental features, if the environmental feature analysis unit 110 intends to generate the synthetic data in the fire field in the building environment from the next environmental feature extraction process, the environmental feature analysis unit 110 adds the ‘pipe’ as the environmental feature.

Referring back to FIG. 3, the synthetic data generation unit 120 may modify a configuration of a synthetic data generation function of the synthetic data generation simulator for the environmental model selected to generate synthetic data to be generated by reflecting the environmental feature extracted by the environmental feature analysis unit 110, and then generate the synthetic data by using the synthetic data generation simulator. Here, the synthetic data generation unit 120 modifies a parameter corresponding for each environmental feature among parameters of the synthetic data generation function or synthetic data generation logic according to the extracted environmental feature to modify the configuration of the synthetic data generation function. The synthetic data generation function or synthetic data generation logic of the synthetic data generation simulator for generating the synthetic data is configured to generate data to which the environmental features of the environmental model are reflected. In particular, since a unique environmental feature is configured to correspond to each parameter of the synthetic data generation function or synthetic data generation logic, the synthetic data generation unit 120 adjusts the parameter of the synthetic data generation function or synthetic data generation logic corresponding to the environmental feature extracted by the environmental feature analysis unit 110 according to the environmental feature to generate synthetic data closer to the actual environment.

Here, additionally, the synthetic data generation unit 120 may match a data feature of the synthetic data generated by the synthetic data generation simulator for a target environmental model with a data feature to which actual data generated in the actual environment belongs.

The data collection unit 130 stores actual data sampled and collected in the actual environment, and transfers the actual data to the synthetic data generation unit 120 by a request of the actual environmental feature analysis unit 110.

When the method for matching the data feature of the synthetic data with the data feature to which the actual data generated in the actual environment belongs is described in detail, the synthetic data generation unit 120 first determines a data distribution region of the synthetic data generated by the synthetic data generation simulator as a data distribution region to which the actual data belongs based on the actual data received through the data collection unit 130. Next, the synthetic data generation unit 120 sets the synthetic data generation simulator to output only synthetic data included in the data distribution region to which the actual data belongs among the synthetic data generated by the synthetic data generation simulator. That is, the synthetic data generation unit 120 sets the synthetic data generation simulator to generate the synthetic data only in the latent space in which the actual data is to be present.

In generating the synthetic data, the synthetic data generation simulator may utilize a generative model such as generative adversarial networks (GAN) and variational auto-encoder (VAE). The generative model may be a model that determines to which distribution given data is likely to belong by learning the distribution of the data (i.e., matches the actual data distribution and the synthetic data distribution). The GAN is constituted by a generator and a discriminator, and the generator performs learning to increase a probability that the discriminator may not identify fake data (corresponding to the synthetic data), and contrary to this, the discriminator performs learning to increase a probability that the fake data of the generator and the actual data are compared and identified. In other words, the generator makes an effort to deceive the discriminator, and the discriminator makes an effort not to deceive the generator. The GAN as the generative model may match the distribution of the actual data and the distribution of the synthetic data through such a process. The variational auto-encoder (VAE) aims at finding a probability distribution that an input is made by learning a mean and a standard deviation for the probability distribution of the latent space. That is, the distribution of the latent space to generate the synthetic data is learned to match the distribution of the synthetic data and the distribution of the actual data.

In the exemplary embodiments as the method for matching the data feature of the synthetic data with the data feature to which the actual data generated in the actual environment belongs, and various generative models (not limited only to the GAN and the VAE) may be used, and the generative model matches the distribution of the actual data and the distribution of the synthetic data better to generate high-quality synthetic data.

The synthetic data quality evaluation unit 140 evaluates the quality of the synthetic data generated by the synthetic data generation unit 120, and when the quality of the synthetic data does not meet a predetermined criterion, the synthetic data quality evaluation unit 140 allows the environmental feature analysis unit 110 to analyze the actual environmental feature again to extract the environmental feature. In this case, the environmental feature analysis unit 110 configures the synthetic data generation function or the synthetic data generation logic of the synthetic data generation simulator again based on the environmental feature which is extracted again, and then, allows the synthetic data generation simulator to generate targeted data.

The quality evaluation of the synthetic data may adopt a direct evaluation method that performs evaluation through a direct comparison of a generated synthetic data set and an original data set (a statistical value comparison, a data distribution comparison, a correlation analysis, etc.), and an indirect evaluation method that evaluates whether the performance of the artificial intelligence model may achieve a reference value by training the artificial intelligence model based on the generated synthetic data.

Hereinafter, the present disclosure will be described in detail through various exemplary embodiments.

### Exemplary Embodiment 1: Communication Data Generation for Learning Communication Scheduling AI Model

In the exemplary embodiment, using the apparatus and the method for generating learning data in generating learning wireless communication data will be described as an example in order to help understanding the present disclosure. In particular, in the exemplary embodiment, an example of generating a communication waveform generated by apparatuses performing wireless communication as the synthetic data will be described.

The synthetic data generated in the exemplary embodiment may be used as an example of communication data generated in a specific environment so as for the artificial intelligence model to present optimal communication scheduling.

Actual data for the communication waveform may have different data distributions according to an actual environment in which a waveform is transmitted or received. Referring to FIG. 1, when it is assumed that environment A is a smart home, environment B is a smart office, and environment C is a smart factory, wireless communication data transmitted in the building corresponding to each environment may have different data distributions such as the data distribution 10 of environment A, the data distribution 20 of environment B, and the data distribution 30 of environment C according to different environmental features.

The synthetic data generation apparatus 1000 selects an environmental model corresponding to an environment to obtain data among environments A, B, and C, and then analyzes a corresponding actual environment based on the environmental model and derives various environmental features such as placement of objects, an electromagnetic wave absorption degree of the placed objects constituting the space, the material of the wall, whether there are communication nodes in a surrounding, etc. In this case, the synthetic data generation apparatus 1000 extracts environmental features based on the ontology representing the correlation between the communication field and the environmental feature.

The synthetic data generation apparatus 1000 modifies the configuration of the synthetic data generation function of the synthetic data generation simulator for the selected environmental model to generate synthetic data to be generated by reflecting the extracted environmental feature, and then generates the synthetic data by using the synthetic data generation simulator. Meanwhile, the synthetic data generation apparatus 1000 acquires a small number of communication data sampled in the actual environment, and then matches the distribution of the synthetic data generated by using the acquired communication data to be closer to the latent space of the actual data. Last, the synthetic data generation apparatus 1000 generates high-quality synthetic communication data according to a data feature derived through a communication data generation simulator.

### Exemplary Embodiment 2: Fire Data Generation for Learning AI Model to be Mounted on Fire Sensor

In collecting fire data for the building, for example, a spread degree and a spread range of the fire may vary depending on the type of apartment plane type, the material of the wall, a material and a location of a furniture, etc., in spite of the same apartment, for example. In the case of fire data, fire prevention is legally prohibited, and fire prevention test cost is also very large, so it is difficult to collect actual fire data.

Therefore, in the exemplary embodiment, synthetic fire data is generated by using an environmental model for an actual environment to obtain the fire data and a fire data generation simulator in the environmental model.

First, the synthetic data generation apparatus 1000 selects a model (e.g., a building information modeling model including a 3D building design, material information of the wall surface, furniture layout information, etc.) for the actual environment that aims at generation of the fire data, and reads the selected model from an environmental model database.

The synthetic data generation apparatus 1000 analyzes and derives the feature for the actual environment based on the selected environmental model. The synthetic data generation apparatus 1000 analyzes and extracts a factor that influences or changes the generation of the fire data in the selected environmental model. The corresponding environmental feature may become the type of apartment plane, the location of the window, the material of the wall, the height of the building, etc. In this case, the synthetic data generation apparatus 1000 extracts the environmental features based on the ontology representing the correlation between the fire field and the environmental feature.

The synthetic data generation apparatus 1000 modifies the configuration of the synthetic data generation function of the synthetic data generation simulator for the selected environmental model to generate synthetic data to be generated by reflecting the extracted environmental feature, and then generates the synthetic data by using the synthetic data generation simulator. In this case, feature information is processed so as to use the feature derived in the environment model for generation of data. That is, the feature information is processed so as to use the feature derived in the actual environment for the environmental model.

The synthetic data generation apparatus 1000 matches the distribution of the synthetic data to be generated by using a small number of communication data sampled in the actual environment to be closer to the data distribution (latent space) to which the actual data belongs. In the exemplary embodiment, since it is difficult to sample the actual data for the actual environment, which aims at the generation of the fire data, actual data (e.g., actual fire data of National Institute of Standards and Technology) collected and opened in an environment similar to the actual environment may be utilized.

Last, the synthetic data generation apparatus 1000 generates high-quality synthetic data by using a fire simulator such Fire Dynamics Simulator (FDS).

### Exemplary Embodiment 3: High-Quality Data Generation for AI Model to be Mounted on Building Air Conditioning System

A heating, ventilation, and air conditioning (HVAC) has a main purpose of creating a fresh environment by adjusting four elements (temperature, humidity, air current, and cleanliness) of air conditioning to a state suitable for an indoor or vehicle environment by integrating heating, ventilation, and cooling. Even indoor spaces having the same structure may show a change in temperature, humidity, air current, and cleanliness having entirely different features according to the location of an air conditioner, the location and the thickness of the window, furniture layout, etc.

An exemplary embodiment of the HVAC is a case of generating different data for four elements such as the temperature, the humidity, the air current, and the cleanliness, and data may have a correlation to each other.

First, the synthetic data generation apparatus 1000 selects a model (e.g., a building information modeling (BIM) model or a digital twin model) for the actual environment aiming at data generation, and reads the selected model from the environmental model database. Since the digital twin model as the environmental model may reflect the degree of aging of the building and the HVAC, the digital twin model may acquire data in which the temperature, the humidity, the air current, and the cleanliness of the actual environment are change differently upon operating the air conditioner according to the degree of aging of the air conditioner. Further, since the digital twin model as the environmental model has information on an air current flow in the building, the digital twin model may acquire accurate air current data according to the operation of the air conditioner.

Next, the synthetic data generation apparatus 1000 samples the actual data for the actual environment, which aims at data generation. The number of data types measurable among four data for four elements may be different due to cost when sampling the actual data. Since the correlation between the data types is well reflected as the number of measurable data types (temperature, humidity, air current, and cleanliness) is larger, higher-quality synthetic data may be generated.

The synthetic data generation apparatus 1000 analyzes and derives the feature for the actual environment based on the environmental model. The synthetic data generation apparatus 1000 analyzes and extracts factors (e.g., the location of the air conditioner, the location and the thickness of the window, a shape of the external wall of the building, the air current flow information in the building, the aging degree of the air conditioner, etc.) which influence or change the data generation for the HVAC in a specific environmental model, and then processes feature information so as to use the feature derived in the environmental model upon generating the high-quality synthetic data. In this case, the synthetic data generation apparatus 1000 extracts the environmental features based on the ontology representing the correlation between the air conditioning field and the environmental feature.

The synthetic data generation apparatus 1000 modifies the configuration of the synthetic data generation function of the synthetic data generation simulator for the selected environmental model to generate synthetic data to be generated by reflecting the extracted environmental feature, and then generates the synthetic data by using the synthetic data generation simulator. Meanwhile, the synthetic data generation apparatus 1000 acquires a small number of air conditioning data sampled in the actual environment, and then matches the distribution of the synthetic data generated by using the acquired communication data to be closer to the data distribution (latent space) to which the actual data belongs to generate the high-quality synthetic data.

Hereinafter, a method of synthetic data generation by using the synthetic data generation apparatus 1000 will be described in detail.

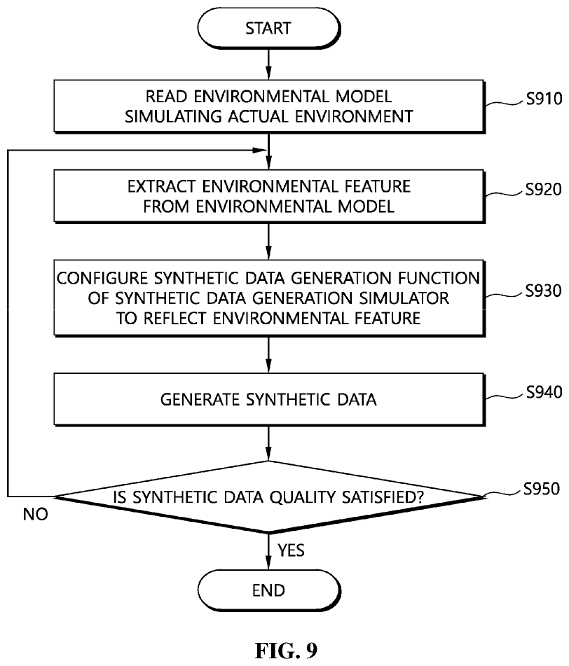

FIG. 9 is a flowchart for describing a method of synthetic data generation according to exemplary embodiments.

Referring to FIGS. 3 and 9, in the learning data generation method by the synthetic data generation apparatus 1000, first, when a user selects an environmental model for an actual environment, which aims at data generation, i.e., an environmental model simulating the actual environment, the selected environmental mode is read from a model database 350 (S910).

Next, the synthetic data generation apparatus 1000 analyzes a feature for the actual environment such as an environmental feature which influences data generation, which a specific space has based on the selected environmental model, and extracts feature information (S920).

The synthetic data generation apparatus 1000 configures a synthetic data generation function of a synthetic data generation simulator for the environmental model by processing the feature information so that the generated synthetic data reflects the environmental feature (S930).

The synthetic data generation apparatus 1000 generates high-quality synthetic data by using the synthetic data generation simulator for the environmental model (S940).

Last, the synthetic data generation apparatus 1000 evaluates the quality of the generated synthetic data, and then, when the generated synthetic data satisfies a required data quality, the synthetic data generation apparatus 1000 terminates the generation of the synthetic data, and when the generated synthetic data does not satisfy the required data quality, the synthetic data generation apparatus 1000 performs the process (S920) of extracting the feature information again (S950).

Here, additionally, the synthetic data generation apparatus 1000 may match a data feature of the synthetic data generated by the synthetic data generation simulator for a target environmental model with a data feature to which actual data generated in the actual environment belongs, in order to generate higher-quality synthetic data.

A matching process of the data feature may include a process of receiving the actual data acquired in the actual environment, a process of determining a data distribution region of synthetic data generated by the synthetic data generation simulator as a data distribution region to which the actual data belongs based on the received actual data, and a process of setting the synthetic data generation simulator to output only the synthetic data included in the data distribution region to which the actual data belongs among the synthetic data generated by the synthetic data generation simulator. In this case, the synthetic data generation apparatus 1000 samples and acquires the actual data in the actual environment aiming at the data generation or the test bed for the actual environment through the data collection unit 130.

In the above description, steps, processes, or operations may be further split into additional steps, processes, or operations or combined as less steps, processes, or operations according to an implementation example of the present disclosure. In addition, some steps, processes, or operations may also be omitted as necessary, and the order between the steps or the operations may also be switched. Further, each step or operation included the learning data generation method may be implemented as a computer program and stored in a computer-readable recording medium, and each step, process, or operation may also be executed by a computing device.

The term “unit” used herein (e.g., a control unit, etc.) may mean, for example, a unit including one or a combination of two or more of hardware, software, or firmware. “Unit” may be used interchangeably with terms such as unit, logic, logical block, component, or circuit, for example. The “unit” may be a minimum unit of an integral part or a portion thereof. The “unit” may be a minimum unit performing one or more functions, and a portion thereof. The “unit” may be implemented mechanically or electronically. For example, the “unit” may include at least one of application-specific integrated circuit (ASIC) chips, field-programmable gate arrays (FPGAs), or programmable-logic devices that perform certain operations and are currently known or will be developed in the future.

At least a portion of a device (e.g., modules or functions thereof) or a method (e.g., operations) according to various embodiments may be implemented using instructions stored in, for example, a computer-readable storage media in the form of a program module. When the instructions are executed by a processor, the one or more processors may perform a function corresponding to the instruction. The computer-readable storage medium may be, for example, a memory.

The computer-readable storage media/computer-readable recording media may include hard disks, floppy disks, magnetic media (e.g., magnetic tape), optical media (e.g., CD-ROM (compact disc read only memory), DVD (digital versatile disc), magnetic-optical media (e.g. floptical disk), hardware devices (e.g., read only memory (ROM), random access memory (RAM), or flash memory), etc. Further, the program instruction may include a high-level language code that may be executed by a computer using an interpreter or the like as well as a machine language code created by a compiler. The above-described hardware device may be configured to operate as one or more software modules to perform operations of various embodiments, and vice versa.

A module or a program module according to various embodiments may include at least one or more of the above-described elements, some of them may be omitted therefrom, or the module or program module may further include additional other elements. Operations performed by a module, a program module, or other components according to various embodiments may be executed in a sequential, parallel, repetitive, or heuristic manner. Further, some operations may be executed in a different order, omitted, or other operations may be added thereto.

As used herein, the singular forms “a”, “an”, and “one” are intended to include the plural forms as well, unless the context clearly indicates otherwise. It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The arrangement of components to achieve the same function is effectively “related” so that the desired function is achieved. Thus, any two components combined to achieve a particular function may be considered to be “related” to each other such that the desired function is achieved, regardless of a structure or am intervening component. Likewise, two components thus related may be considered to be “operably connected” or “operably coupled” to each other to achieve the desired function.

Further, one of ordinary skill in the art will recognize that a boundary between the functionalities of the aforementioned operations is merely exemplary. A plurality of operations may be combined into a single operation. A single operation may be divided into additional operations. Operations may be executed in an at least partially overlapping manner in time. Further, alternative embodiments may include a plurality of instances of a specific operation. The order of operations may vary in various other embodiments. However, other modifications, variations and alternatives may be present. Accordingly, the detailed description and drawings should be regarded as illustrative and not restrictive.

The phrase “may be X” indicates that the condition X may be satisfied. This phrase also indicates that condition X may not be satisfied. For example, a reference to a system that contains a specific component should also include a scenario where the system does not contain the specific component. For example, a reference to a method containing a specific operation should also include a scenario where the corresponding method does not contain the specific operation. However, in another example, a reference to a system configured to perform a specific operation should also include a scenario where the system is configured not to perform the specific operation.

The terms “comprising”, “having”, “composed of”, “consisting of” and “consisting essentially of” are used interchangeably. For example, any method may include at least an operation included in the drawing and/or specification, or may include only an operation included in the drawings and/or specification.

Those of ordinary skill in the art may appreciate that the boundaries between logical blocks are merely exemplary. It will be appreciated that alternative embodiments may combine logical blocks or circuit elements with each other or may functionally divide various logical blocks or circuit elements. Therefore, a architecture shown herein is only exemplary. In fact, it should be understood that various architectures may be implemented that achieve the same function.

Further, for example, in one embodiment, the illustrated examples may be implemented on a single integrated circuit or as a circuit located within the same device. Alternatively, the examples may be implemented as any number of individual integrated circuits or individual devices interconnected with each other in a suitable manner. Other changes, modifications, variations and alternatives may be present. Accordingly, the specification and drawings are to be regarded as illustrative and not restrictive.

Further, for example, the examples or some of thereof may be implemented using physical circuits such as any suitable type of hardware description language, or software or code representations of logical representations convertible to physical circuits.

Further, the present disclosure is not limited to a physical device or unit implemented as non-programmable hardware, but may be applied to a programmable device or unit capable of performing a desired device function by operating according to an appropriate program code, such as a main frame generally referred to as a ‘computer system’, a mini computer, server, workstation, personal computer, notepad, PDA, electronic game player, automobiles and other embedded systems, mobile phones and various other wireless devices, etc.

A system, device or device mentioned herein may include at least one hardware component.

Connection as described herein may be any type of connection suitable for transmitting a signal from or to each node, unit or device via an intermediate device, for example. Thus, unless implied or otherwise stated, the connection may be direct connection or indirect connection, for example. Connection may include single connection, multiple connection, one-way connection or two-way connection. However, different embodiments may have different implementations of the connection. For example, separate one-way connection may be used rather than two-way connection, and vice versa. Further, a plurality of connections may be replaced with a single connection in which a plurality of signals are transmitted sequentially or in a time multiplexing scheme. Likewise, a single connection in which a plurality of signals are transmitted may be divided into various connections in which subsets of the signals are transmitted. Thus, there are many options for transmitting the signal.

In the claims, any reference signs placed between parentheses shall not be construed as limiting the claim. The word ‘comprising’ does not exclude the presence of elements or operations listed in a claim.

In the above descriptions, the preferred embodiments of the present disclosure have been described with reference to the accompanying drawings. The terms or words used herein and claims should not be construed as being limited to a conventional or dictionary meaning, and should be interpreted as a meaning and concept consistent with the technical idea of the present disclosure. The scope of the present disclosure is not limited to the embodiments disclosed herein. The present disclosure may be modified, altered, or improved in various forms within the scope of the spirit and claims of the present disclosure.

What is claimed is:

1. A method of synthetic data generation for training an artificial intelligence model, the method comprising:
reading a target environmental model simulating a target environment to generate synthetic data among a plurality of environmental models simulating a plurality of actual environments, respectively;
extracting an environmental feature which influences generation of data in the target environment;
configuring a synthetic data generation function of a synthetic data generation simulator for the target environmental model so that the synthetic data reflects the environmental feature; and
generating the synthetic data by using the synthetic data generation simulator for the target environmental model.

2. The method of claim 1, wherein the extracting of the environmental feature which influences generation of data in the target environment is extracting the environmental feature based on a correlation between the target environment and an application field of the synthetic data.

3. The method of claim 2, wherein the correlation between the target environment and the application field of the synthetic data is determined based on ontology related to the target environment and the application field of the synthetic data.

4. The method of claim 3, wherein the configuring of the synthetic data generation function of the synthetic data generation simulator for the target environmental model so that the synthetic data reflects the environmental feature is modifying a parameter corresponding to each environmental feature among parameters of the synthetic data generation function according to the environmental feature.

5. The method of claim 1, further comprising:
matching the data feature of the synthetic data generated by the synthetic data generation simulation for the target environmental model with a data feature to which the actual data generated in the target environment belongs.

6. The method of claim 5, wherein the matching of the data feature of the synthetic data generated by the synthetic data generation simulation for the target environmental model with the data feature to which the actual data generated in the target environment belongs includes
receiving the actual data acquired in the target environment,
determining a data distribution region of the synthetic data generated by the synthetic data generation simulator for the actual data as a data distribution region to which the actual data belongs, and
setting the synthetic data generation simulator to output only synthetic data included in the data distribution region to which the actual data belongs among the synthetic data generated by the synthetic data generation simulator.

7. An apparatus of synthetic data generation for training an artificial intelligence model, the method comprising:
an environmental model database storing environmental models simulating a plurality of actual environments, respectively;
an environmental feature analysis unit reading, from the environmental model database, a target environmental model simulating a target environment to generate synthetic data among the plurality of environmental models, and extracting an environmental feature which influences generation of data in the target environment; and
a synthetic data generation unit configuring a synthetic data generation function of a synthetic data generation simulator for the target environmental model so that the synthetic data reflects the environmental feature, and generating the synthetic data by suing the synthetic data generation simulator for the target environmental model.

8. The apparatus of claim 7, wherein the environmental feature analysis unit extracts the environmental feature based on a correlation between the target environment and an application field of the synthetic data.

9. The apparatus of claim 8, wherein the environmental feature analysis unit determines the correlation based on ontology related to the target environment and the application field of the synthetic data.

10. The apparatus of claim 9, wherein the synthetic data generation unit modifies a parameter corresponding to each environmental feature among parameters of the synthetic data generation function according to the environmental feature.

11. The apparatus of claim 7, further comprising:
a data collection unit collecting actual data acquired in the target environment,
wherein the synthetic data generation units further matches the data feature of the synthetic data generated by the synthetic data generation simulation for the target environmental model with a data feature to which the actual data belongs.

12. The apparatus of claim 11, wherein the synthetic data generation unit
determines a data distribution region of the synthetic data generated by the synthetic data generation simulator for the actual data as a data distribution region to which the actual data belongs, and
sets the synthetic data generation simulator to output only synthetic data included in the data distribution region to which the actual data belongs among the synthetic data generated by the synthetic data generation simulator.

13. An electronic device for synthetic data generation for training an artificial intelligence model, the electronic device comprising:
a communication circuit;
a memory; and
a processor operatively connected to the memory,
wherein when the memory is executed, the processor
reads a target environmental model simulating a target environment to generate synthetic data among a plurality of environmental models simulating a plurality of actual environments, respectively,
extracts an environmental feature which influences generation of data in the target environment,
configures a synthetic data generation function of a synthetic data generation simulator for the target environmental model so that the synthetic data reflects the environmental feature, and
stores instructions to generate the synthetic data by using the synthetic data generation simulator for the target environmental model.

14. The electronic device of claim 13, wherein the instructions allow the processor to
extract an environmental feature which influences generation of data in the target environment, and
extract the environmental feature based on a correlation between the target environment and an application field of the synthetic data.

15. The electronic device of claim 14, wherein the instructions allow the processor to determine the correlation based on ontology related to the target environment and the application field of the synthetic data.

16. The electronic device of claim 15, wherein the instructions allow the processor to modify a parameter corresponding to each environmental feature among parameters of the synthetic data generation function according to the environmental feature.

17. The electronic device of claim 13, wherein the instructions allow the processor to match the data feature of the synthetic data generated by the synthetic data generation simulation for the target environmental model with a data feature to which the actual data generated in the target environment belongs.

18. The electronic device of claim 17, wherein the instructions allow the processor to
receive actual data acquired in the target environment,
determine a data distribution region of the synthetic data generated by the synthetic data generation simulator for the actual data as a data distribution region to which the actual data belongs, and
set the synthetic data generation simulator to output only synthetic data included in the data distribution region to which the actual data belongs among the synthetic data generated by the synthetic data generation simulator.
